(19) United States
(12) Patent Application Publication
(10) Pub. No.: US 2012/0139048 A1
(43) Pub. Date: Jun. 7, 2012

(54) MOSFET AND METHOD FOR MANUFACTURING THE SAME

(75) Inventors: Huilong Zhu, Poughkeepsie, NY (US); Miao Xu, Beijing (CN); Qingqing Liang, Beijing (CN)

(73) Assignee: Institute of Microelectronics, Chinese Academy of Sciences, Beijing (CN)

(21) Appl. No.: 13/140,744

(22) PCT Filed: Mar. 4, 2011
(86) PCT No.: PCT/CN11/71537

§ 371 Date: Jun. 17, 2011

(30) Foreign Application Priority Data
Dec. 3, 2010 (CN) 201010573334.X

(51) Int. Cl. H01L 29/772; H01L 21/336

(52) U.S. Cl. 257/348; 438/289; 257/E29.242; 257/E21.409

(57) ABSTRACT

The present application discloses a MOSFET and a method for manufacturing the same. The MOSFET comprises an SOI chip comprising a semiconductor substrate, a buried insulating layer on the semiconductor substrate, and a semiconductor layer on the buried insulating layer; source/drain regions formed in the semiconductor layer; a channel region formed in the semiconductor layer and located between the source/drain regions; and a gate stack comprising a gate dielectric layer on the semiconductor layer, and a gate conductor on the gate dielectric layer, wherein the MOSFET further comprises a backgate formed in a portion of the semiconductor substrate below the channel region, and the backgate has a non-uniform doping profile, and wherein the buried insulating layer serves as a gate dielectric layer of the backgate. The MOSFET has an adjustable threshold voltage by changing the type of dopant and/or the doping profile in the backgate, and reduces a leakage current of the semiconductor device.

### BACKGROUND OF THE INVENTION

1. Field of Invention

The present invention relates to a MOSFET and a method for manufacturing the same, and more particularly, to a MOSFET comprising a backgate and a method for manufacturing the same.

2. Description of Related Art

One important trend in the integrated circuits is scaling down of Metal-Oxide-Semiconductor Field Effect Transistors (MOSFETs), which achieves a high integration degree of semiconductor devices and reduces manufacturing cost. However, it is well known that a short channel effect occurs with a reduced size of the MOSFET. When the size of MOSFET is scaled down, a gate of the MOSFET has a smaller effective length and actually controls fewer charges in a depletion region when a gate voltage is applied. Consequently, the MOSFET has a reduced threshold voltage with a reduced channel length.

In a MOSFET, it is desirable on one hand to increase the threshold voltage of the semiconductor device so as to suppress the short channel effect. On the other hand, it is also desirable to decrease the threshold voltage of the semiconductor device so as to reduce power consumption, for example, in a low voltage application, and an application using both a p-type MOSFET and an n-type MOSFET.

Channel doping is a known approach to have an adjustable threshold voltage. However, carrier mobility is possibly decreased when doping concentration of the channel region is increased for a higher threshold voltage of the device, which deteriorates the properties of the semiconductor device. Moreover, the ions in the channel region with high doping concentration possibly neutralize the ions in source/drain regions and in regions adjacent to the channel region. The concentration of the ions in the regions adjacent to the channel region is thus decreased, which in turn increase resistance of the semiconductor device.

It is disclosed in “Scaling the Si MOSFET: From bulk to SOI to bulk”, Yan et al., IEEE Trans. Elect. Dev., Vol. 39, p. 1704, June, 1992 that a ground plane (i.e., a backgate being grounded) can be arranged below a buried oxide layer for suppressing the short channel effect in an SOI MOSFET.

However, the above SOI MOSFET comprising a grounded backgate may not meet the requirement of the threshold voltage when the channel length of the semiconductor device continues to decrease.

Therefore, it is still desirable that the threshold voltage of the semiconductor device is adjusted in a controllable manner while the properties of the semiconductor device are not deteriorated without increasing the doping concentration in the channel.

### SUMMARY OF THE INVENTION

The object of the present invention is to provide a MOSFET having a threshold voltage adjustable by using a backgate.

According to one aspect of the present invention, there provides a MOSFET comprising an SOI chip comprising a semiconductor substrate, a buried insulating layer on the semiconductor substrate, and a semiconductor layer on the buried insulating layer; source/drain regions formed in the semiconductor layer; a channel region formed in the semiconductor layer and located between the source/drain regions; and a gate stack comprising a gate dielectric layer on the semiconductor layer, and a gate conductor on the gate dielectric layer, wherein the MOSFET further comprises a backgate formed in a portion of the semiconductor substrate below the channel region, and the backgate has a non-uniform doping profile, and wherein the buried insulating layer serves as a gate dielectric layer of the backgate. In the MOSFET, the buried insulating layer is preferably a buried oxide layer.

According to another aspect of the present invention, there provides a method for manufacturing a MOSFET, comprising: a) providing an SOI chip comprising a semiconductor substrate, a buried insulating layer on the semiconductor substrate, and a semiconductor layer on the buried insulating layer; b) forming a gate stack on the semiconductor layer, the gate stack comprising a gate dielectric layer and a gate conductor on the gate dielectric layer; c) performing an ion implantation for a backgate to the semiconductor substrate so as to form an ion implanted region; d) performing an annealing after the ion implantation so that the ion implanted region extends laterally to form a backgate in a portion of the semiconductor substrate below the gate conductor, wherein the backgate has a non-uniform doping profile; and e) performing a source/drain ion implantation to the semiconductor layer so as to form source/drain regions

In the inventive MOSFET, a backgate is formed from the semiconductor substrate, and the buried insulating layer serves as the gate dielectric layer of the backgate. When applying a control voltage to the backgate, the resultant electric field is applied to the channel region through the buried insulating layer. Due to the non-uniform doping profile in the backgate, the threshold voltage can be adjusted as required by changing the type of dopant and/or the doping profile in the backgate.

### BRIEF DESCRIPTION OF THE DRAWINGS

FIGS. 1-6 schematically show cross-sectional views of the semiconductor structure at various stages of the method for manufacturing an ultra-thin MOSFET according to the present invention.

### DETAILED DESCRIPTION OF EMBODIMENTS

Exemplary embodiments of the present invention are described in detail below with reference to the accompanying drawings. In the drawings, like reference numerals denote like components. The figures are not drawn to scale for the sake of clarity. Some particular details of the invention will be described, such as exemplary structures, materials, dimensions, process steps and fabricating methods of the semiconductor device, for a better understanding of the present invention.

Nevertheless, it is understood by one skilled person in the art that these details are not always necessary, but can be varied in specific implementation of the invention. Unless the context clearly indicates otherwise, each part of the semiconductor device can be made of material(s) well-known to one skilled person in the art.

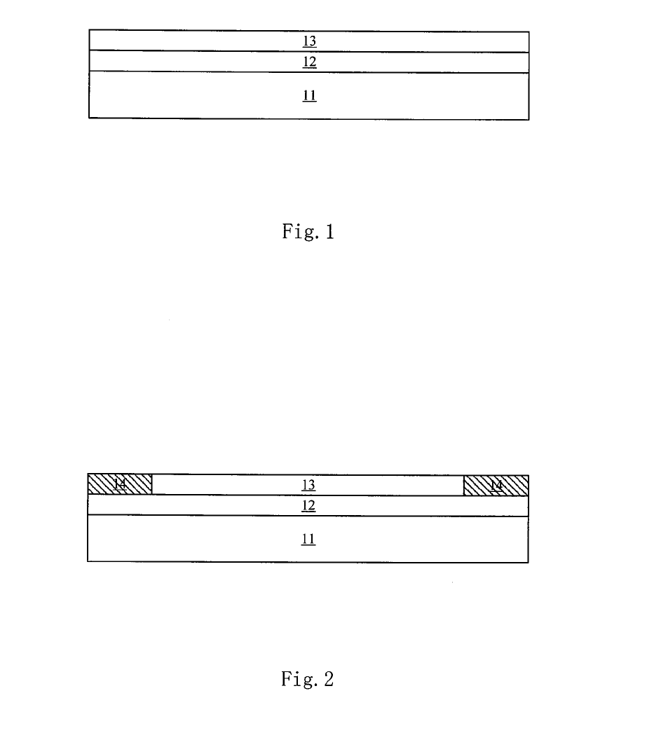

According to one preferred embodiment of the present invention, the steps shown in FIGS. 1 to 6 are performed in sequence for manufacturing the ultra-thin SOI MOSFET.

As shown in FIG. 1, a typical SOI chip serves as an initial structure of the semiconductor substrate, and comprises a semiconductor substrate 11, a buried oxide layer 12 and a semiconductor layer 13 from bottom to top. The semiconductor layer 13 has a thickness of about 5-20 nm, and the buried oxide layer 12 has a thickness of about 5-30 nm. The buried oxide layer 12 can also be other buried insulating layer.

The semiconductor substrate 11 will be used for providing a backgate for the MOSFET, and the buried oxide layer 12 will be used as a gate dielectric layer for the backgate. The semiconductor layer 13 may be made of a semiconductor material selected from a group consisting of group-IV semiconductors (such as silicon or germanium) and group III-V compound semiconductors (such as gallium arsenide). For example, the semiconductor layer 13 is made of single crystalline silicon or single crystalline SiGe. The semiconductor layer 13 will be used for providing source/drain regions and the channel region of the MOSFET.

The process for providing an SOI chip is well known in the art. For example, the SmartCut™ process (referred as “Smart Cut” or “Smart Strip”) can be used for this purpose. The SmartCut™ process comprises the steps of: bonding two chips with each other, wherein each of the chips has a surface oxide layer formed by thermal oxidation or deposition, and one of the chips is subjected to hydrogen implantation so as to form a hydrogen implantation region at a predetermined depth in the silicon body below the surface oxide layer; and converting the hydrogen implantation region to a layer having micro-cavities under the conditions of an increased pressure and an increased temperature so as to separate chips, wherein the other one of the two chips serves as an SOI chip. By controlling parameters in the process of thermal oxidation or deposition, the thickness of the buried oxide layer in the SOI chip can be controlled. By controlling implantation energy during the hydrogen implantation, the thickness of the top semiconductor layer in the SOI chip can be controlled.

A trench is then formed by patterning the semiconductor layer 13. An insulating material is filled into the trench so as to form a shallow trench isolation (STI) 14 for defining an active region of the MOSFET, as shown in FIG. 2.

The patterning process may involve the following steps: forming a photoresist mask having patterns on the semiconductor layer 13 by a conventional lithographical process including exposure and development; removing the exposed portions of the semiconductor layer 13 by dry etching such as ion beam milling, plasma etching, reactive ion etching, laser ablation and the like, or by wet etching using a solution of etchant, wherein the etching stops on top of the buried oxide layer 12; and removing the photoresist mask by ashing or dissolution with a solvent.

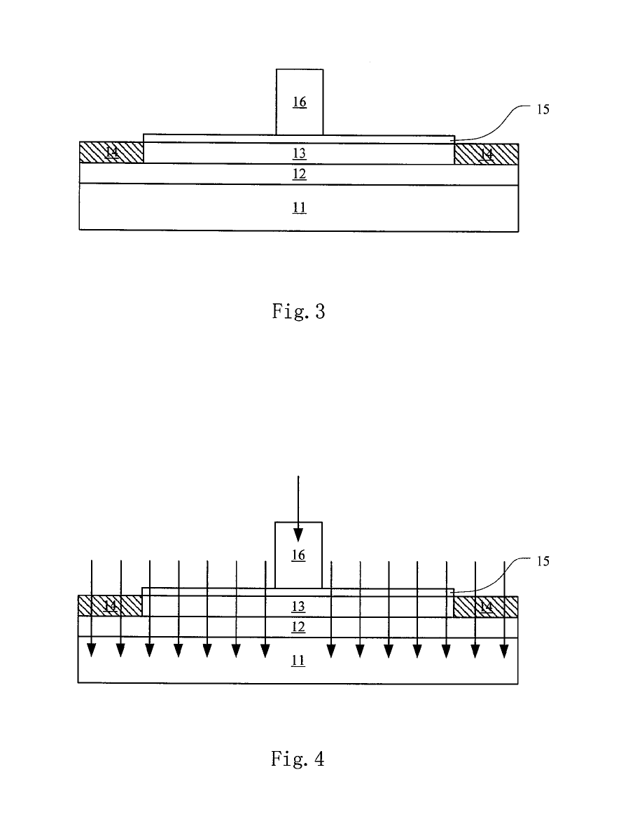

A gate stack is then formed on the semiconductor layer 13, as shown in FIG. 3. The gate stack comprises a gate dielectric layer 15 having a thickness of about 1-4 nm and a gate conductor 16 having a thickness of about 30-100 nm. The deposition process and patterning processes for forming the gate stack is known in the art. The gate conductor 16 is typically patterned into stripes.

The gate dielectric layer 15 is made of one or more of oxides, oxynitrides, and high-K materials. The gate conductor 16 can be, for example, a metal layer, a doped polysilicon layer, or a stacked gate conductor including a metal layer and a doped polysilicon layer.

The channel region comprises a portion (not shown) of the semiconductor layer 13 below the gate stack, and is preferably undoped, or self-doped, or doped in a previous independent ion implantation process.

An ion implantation is then performed through the gate dielectric layer 15, the semiconductor layer 13 and the buried oxide layer 12 to the semiconductor substrate 11, as shown in FIG. 4. Because the total thickness of the gate dielectric layer 15, the semiconductor layer 13 and the buried oxide layer is only about 10-50 nm, the implanted ions may easily penetrate these layers and enter into the semiconductor substrate 11. The implantation depth may be controlled by adjusting implantation energy, so that the implanted ions are mainly distributed in the semiconductor substrate 11.

The ion implantation region can be located in the upper portion of the semiconductor substrate 11, and have a distance from the overlying buried oxide layer 12, without adjoining the overlying buried oxide layer 12 (not shown).

The doping profile in the ion implantation process is determined by the angle of ion implantation. If the ion implantation for the backgate is performed in a direction perpendicular to the main surface of the SOI chip, an undoped region will be formed in a portion of the semiconductor substrate below the gate conductor, and the implanted region will be formed in other portions of the semiconductor substrate (see FIG. 4). If the ion implantation for the backgate is performed at an oblique angle, an implanted region having a first doping concentration will be formed in a portion of the semiconductor substrate below the gate conductor, and an implanted region having a second doping concentration will be formed in other portions of the semiconductor substrate (not shown). The first doping concentration is higher than the second doping concentration.

The type and the doping profile in the ion implantation are determined by the type of the MOSFET and the target value of the threshold voltage. In order to increase the threshold voltage, the doping profiled shown in FIG. 4 may be used. For a p-type MOSFET, P-type dopants may be used, such as boron (B or BF2), indium (In) or their combinations; and for an n-type MOSFET, n-type dopants may be used, such as arsenic (As), phosphorus (P) or their combinations. In order to decrease the threshold voltage, the doping profile opposite to that shown in FIG. 4 may be used. That is, the portion of the semiconductor substrate below the gate conductor has a doping concentration higher than that of other portions of the semiconductor substrate. For a p-type MOSFET, n-type dopants may be used, such as arsenic (As), phosphorus (P) or their combinations; and for an n-type MOSFET, p-type dopants may be used, such as boron (B or BF2), indium (In) or their combinations. The dose of the implanted dopants may be determined according to the thickness, which is, for example, about 1e15-1e20/cm³.

Then, a short-time annealing is performed after the ion implantation, which is known as spike annealing, for example by using laser, electron beam or infrared radiation, so as to repair damages in the lattice and activate the implanted dopants. The annealing after the ion implantation may lead to diffusion of the implanted dopants again, and provides a doping profile extending laterally into the undoped region below the gate conductor 16 so as to form a doped backgate 17 in the semiconductor substrate 13.

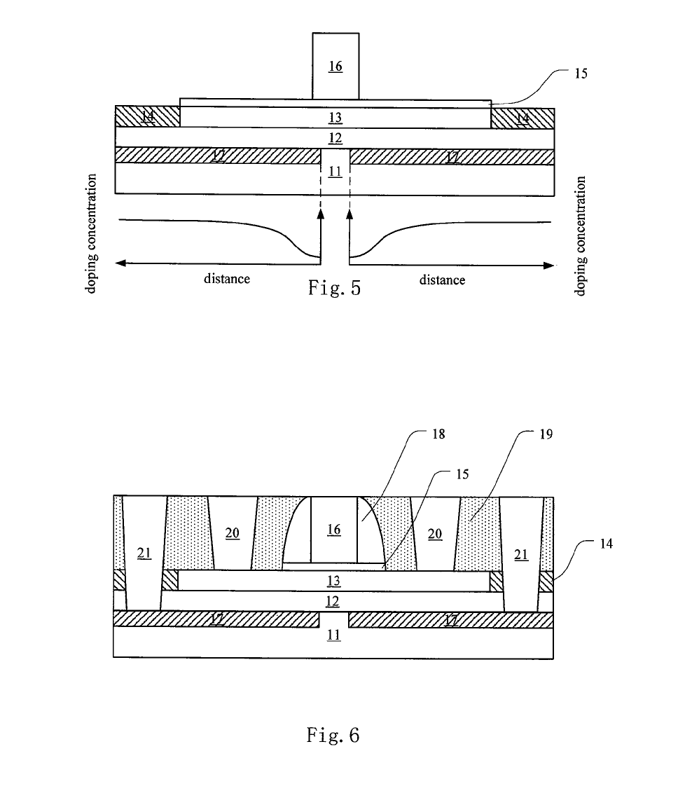

Due to the lateral diffusion of the dopants, the backgate 17 has a doping concentration below the channel region which decreases gradually towards the center of the channel region and reach to zero at the center of the channel region, such that the backgate 17 has uninterconnected two portions being adjacent to the source/drain regions, respectively (see FIG. 5, which shows the doping profile in the backgate).

Alternatively, if the annealing after the ion implantation is performed for a sufficiently long time, the two portions of the backgate may be interconnected because of lateral diffusion of the dopants. Due to the lateral diffusion, the backgate 17 has a doping concentration below the channel region which still decreases gradually towards the center of the channel region and reach to a minimum value (but not zero) at the center of the channel region.

As mentioned above, if the ion implantation for the backgate is performed at an oblique angle, the doping profile will be opposite to that shown in FIG. 5. Due the lateral diffusion of the dopants, the backgate 17 has a doping concentration (not shown) below the channel region which increases gradually towards the center of the channel region.

However, it is not desirable that the annealing after ion implantation is performed at an excessively high temperature and/or for an excessively long time, which may completely eliminate the non-uniform doping profile and provide the same doping concentration everywhere below the channel region.

A conventional CMOS process is then performed, including source/drain ion implantation for forming source/drain regions (not shown) in the semiconductor layer 13, formation of sidewall spacers 18 around the gate conductor, formation of an interlayer dielectric layer 19 on the semiconductor structure, formation of electrically conductive vias 20 being through the interlayer dielectric layer 19 and connected with the source/drain regions, formation of two electrically conductive vias 21 being through the interlayer dielectric layer 19, the shallow trench isolation 14 and the buried oxide layer 12 and connected with the two portions of the backgate 17, respectively. The resultant SOI MOSFET has a device structure shown in FIG. 6.

In the inventive SOI MOSFET, the semiconductor substrate 13 provides a conductor of the backgate, and the buried oxide layer serves as the gate dielectric layer of the backgate. When applying a control voltage to the backgate, the resultant electric field is applied to the channel region through the buried oxide layer. Due to the non-uniform doping profile in the backgate, the threshold voltage can be adjusted in accordance with the length of the channel region. For example, if the length of the channel region of the semiconductor device decreases, the threshold voltage will possibly decrease. The threshold voltage of the semiconductor device can be increased by doping the backgate with the dopants of the same type as the type of the conductivity of the SOI MOSFET. On the contrary, if the threshold voltage is too large, the threshold voltage of the semiconductor device can be decreased by doping the backgate with the dopants of the type opposite to the type of the conductivity of the SOI MOSFET.

In one embodiment of the present application, a doped backgate is formed and the channel region is preferably undoped, which avoid formation of a p-n junction between the channel region and the source/drain region and in turn reduces leakage current of the semiconductor device.

Although the invention has been described with reference to specific embodiments, the description is only illustrative of the invention. The description is not construed as limiting the invention. Various modifications and applications may occur for those skilled in the art without departing from the true spirit and scope of the invention as defined by the appended claims.

1. A MOSFET, comprising
an SOI chip comprising a semiconductor substrate, a buried insulating layer on the semiconductor substrate, and a semiconductor layer on the buried insulating layer;
source/drain regions formed in the semiconductor layer;
a channel region formed in the semiconductor layer and located between the source/drain regions; and
a gate stack comprising a gate dielectric layer on the semiconductor layer and a gate conductor on the gate dielectric layer,
wherein the MOSFET further comprises a backgate formed in a portion of the semiconductor substrate below the channel region, and the backgate has a non-uniform doping profile, and
wherein the buried insulating layer serves as a gate dielectric layer of the backgate.

2. The MOSFET according to claim 1, wherein the backgate has a doping concentration which decreases gradually towards the center of the channel region.

3. The MOSFET according to claim 2, wherein the backgate has a doping concentration which decreases gradually towards the center of the channel region and reach to zero at the center of the channel region, such that the backgate has uninterconnected two portions being adjacent to the source/drain regions, respectively.

4. The MOSFET according to claim 1, wherein the backgate is doped with dopants of the same type as the type of the conductivity of the MOSFET.

5. The MOSFET according to claim 1, wherein the backgate has a doping concentration which increases gradually towards the center of the channel region.

6. The MOSFET according to claim 1, wherein the backgate is doped with dopants of the type opposite to the type of the conductivity of the MOSFET.

7. The MOSFET according to claim 1, wherein the semiconductor layer is made of one of Si and SiGe.

8. The MOSFET according to claim 1, wherein the semiconductor layer has a thickness of 5-20 nm, and the buried insulating layer has a thickness of 5-30 nm.

9. The MOSFET according to claim 1, wherein the buried insulating layer is a buried oxide layer.

10. A method for manufacturing a MOSFET, comprising:
a) providing an SOI chip comprising a semiconductor substrate, a buried insulating layer on the semiconductor substrate, and a semiconductor layer on the buried insulating layer;
b) forming a gate stack on the semiconductor layer, the gate stack comprising a gate dielectric layer and a gate conductor on the gate dielectric layer;
c) performing an ion implantation for a backgate to the semiconductor substrate so as to form an ion implanted region;
d) performing an annealing after the ion implantation so that the ion implanted region extends laterally to form a backgate in a portion of the semiconductor substrate below the gate conductor, wherein the backgate has a non-uniform doping profile; and
e) performing a source/drain ion implantation to the semiconductor layer so as to form source/drain regions.

11. The method according to claim 10, wherein in step c), the ion implantation for the backgate is performed in a direction perpendicular to a main surface of the SOI chip, so that an undoped region is formed in a portion of the semiconductor substrate below the gate conductor, and doped regions are formed in other portions of the semiconductor substrate.

12. The method according to claim 10, wherein in step c), the dopant used in the ion implantation is of the same type as the type of the conductivity of the MOSFET.

13. The method according to claim 10, wherein in step c), the ion implantation for the backgate is performed at an oblique angle, so that an implanted region having a first doping concentration is formed in a portion of the semiconductor substrate below the gate conductor, and an implanted region having a second doping concentration is formed in other portions of the semiconductor substrate, and wherein the first doping concentration is higher than the second doping concentration.

14. The method according to claim 10, wherein in step c), the dopant used in the ion implantation is of a type opposite to the type of the conductivity of the MOSFET.

15. The method according to claim 10, wherein in step c), the dose of the implanted dopant is 1e15-1e20/cm³.

16. The method according to claim 10, wherein in step c), the ion implanted region is formed at an upper portion of the semiconductor substrate.

17. The method according to claim 11, wherein in step d), the backgate has a doping concentration which decreases gradually towards the center of the channel region.

18. The method according to claim 17, wherein in step d), the backgate has a doping concentration which decreases gradually towards the center of the channel region and reach to zero at the center of the channel region, such that the backgate has uninterconnected two portions being adjacent to the source/drain regions, respectively.

19. The method according to claim 13, wherein in step d), the backgate has a doping concentration which increases gradually towards the center of the channel region.

20. The method according to claim 10, wherein the buried insulating layer is a buried oxide layer.
